(19) United States
(12) Patent Application Publication
(10) Pub. No.: US 2002/0075023 A1
(43) Pub. Date: Jun. 20, 2002

(54) Method for electrically testing a wafer interposer

(75) Inventor: John L. Pierce, Dallas, TX (US)

Correspondence Address: Daniel J. Chalker, Gardere Wynne Sewell L.L.P., 3000 Thanksgiving Tower, 1601 Elm Street, Dallas, TX, 75201-4761, US

(73) Assignee: Micro-ASI, Inc., Dallas, TX (US)

(21) Appl. No.: 09/737,923

(22) Filed: Dec. 15, 2000

(51) Int. Cl. G01R 31/02; G01R 31/26

(52) U.S. Cl. 324/758; 324/765

(57) ABSTRACT

The present invention comprises various embodiments of an apparatus and method for electrically testing an integrated circuit wafer interposer assembly. In certain embodiments, the wafer interposer assembly is fixed into a positioning device and moved over a test head to precisely align the contact pads for one device with the contacts of the test head. In certain embodiments, the positioning device facilitates temperature controlled testing of the wafer. In certain embodiments, multiple devices can be tested simultaneously in parallel.

### FIELD OF THE INVENTION

The present invention relates generally to the field of integrated circuit testing, and in particular to the testing of integrated circuit wafers having interposers attached thereto.

### BACKGROUND OF THE INVENTION

Semiconductor die have traditionally been electrically connected to a package by wire bonding techniques, in which wires are attached to pads of the die and to pads located in the cavity of the plastic or ceramic package. Wire bonding is still the interconnection strategy most often used in the semiconductor industry today, but the growing demand for products that are smaller, faster, less expensive, more reliable and have a reduced thermal profile has pushed wire bonding technology to its limits (and beyond) thereby creating barriers to sustained product improvement and growth.

One high-performance alternative to wire bonding techniques is the flip chip technique, in which solder balls or bumps are attached to the input/output (I/O) pads of the die at the wafer level. The bumped die is flipped over and attached to a substrate “face down,” rather than “face up” as is the case with wire bonding. Flip chips resolve many if not all of the problems introduced by wire bonding. First, flip chip packages have fewer electrical interconnects than wire bond packages, which results in improved reliability and fewer manufacturing steps, thereby reducing production costs. Second, the face down mounting of a flip chip die on a substrate allows superior thermal management techniques to be deployed relative to those available in wire bonding. Third, flip chips allow I/O connections to be located essentially anywhere on the die, within the limits of substrate pitch technology and manufacturing equipment, instead of forcing I/O to the peripheral of the die as in wire bonding. This results in increased I/O density and system miniaturization.

Despite the advantages of the flip chip, wide spread commercial acceptance of the flip chip has been hindered by testing issues. To ensure proper performance, the die should be adequately tested before it is assembled into a product; otherwise, manufacturing yields at the module and system level can suffer and be unacceptably low. Under some circumstances, a defective die can force an entire subassembly to be scrapped. One attempt to address this testing issue has been to perform a wafer probe, followed by dicing the wafer and temporarily packaging each die into a test fixture of some sort. Performance testing is subsequently executed. Burn-in testing is often included in this process to eliminate any die having manufacturing process defects. Following the successful completion of these tests, the die are removed from the test fixture and either retailed as a Known Good Die (“KGD”) product or used by the manufacturer in an end product, such as a Multichip Module (“MCM”). The Multichip Module may constitute a subassembly in a larger system product. This Known Good Die process is inherently inefficient due to its complexity.

Electrical test of semiconductor devices occurs several times prior to completion of the manufacturing process. The first test is wafer probe. This test is performed before the wafer is diced into individual circuits. Because of parasitic capacitance and inductance inherent in wafer probe needles, wafer probe testing cannot evaluate the device at its full frequency capability. As a result, full electrical testing occurs after the circuit is enclosed in a semiconductor package. If burn-in of the circuit is required, full electrical testing occurs before and after the burn-in process. Accordingly, there is a need for a method of electrically testing die in wafer form prior to dicing the wafer into individual circuits.

### SUMMARY OF THE INVENTION

The following summary of the invention is provided to facilitate an understanding of some of the innovative features unique to the present invention, and is not intended to be a full description. A full appreciation of the various aspects of the invention can be gained by taking the entire specification, claims, drawings, and abstract as a whole.

The present invention provides a method for electrically testing a wafer interposer that overcomes the limitations of testing bare singulated die. More specifically, the present invention provides a method for testing die in wafer form prior to dicing the wafer into individual circuits.

In one embodiment, the present invention comprises a method for testing an integrated circuit disposed in a semiconductor wafer by attaching an interposer having one or more electrical contacts to the semiconductor wafer, fixing the semiconductor wafer in a holding mechanism attached to a positioning device in such a manner that all or part of the surface of the interposer is accessible, adjusting the position of the positioning device to bring one or more electrical contacts of the interposer into contact with one or more electrical contacts of a test head, and testing the integrated circuit through the electrical contacts of the test head.

In a second embodiment, the present invention comprises a method for testing an integrated circuit disposed in a semiconductor wafer by providing an interposer having a first array of contacts on a first side and a second array of contacts, each electrically connected to one of the contacts in the first array, on a second side, attaching the semiconductor wafer to the first side of the interposer, fixing the semiconductor wafer in a holding mechanism attached to a positioning device, adjusting the position of the positioning device to align one or more of the contacts in the second array with one or more electrical contacts of a test head, adjusting the position of the positioning device to bring one or more of the contacts in the second array into contact with one or more electrical contacts of the test head; and testing the integrated circuit through the electrical contacts of the test head.

In a third embodiment, the present invention comprises a method for testing one or more integrated circuit devices disposed in a semiconductor wafer by providing an interposer having a first array of contacts on a first side and a second array of contacts, each electrically connected to one of the contacts in the first array, on a second side; attaching the semiconductor wafer to the first side of the interposer, fixing the wafer and interposer assembly in a holding mechanism attached to a positioning device, adjusting the position of the positioning device to bring one or more of the contacts in the second array into contact with one or more electrical contacts of the test head, testing the one or more integrated circuit devices through the electrical contacts of the test head, singulating the wafer and interposer assembly into individual integrated circuit devices, and sorting the individual integrated circuit devices according to the results of the tests performed on each device.

The novel features of the present invention will become apparent to those of skill in the art upon examination of the following detailed description of the invention or can be learned by practice of the present invention. It should be understood, however, that the detailed description of the invention and the specific examples presented, while indicating certain embodiments of the present invention, are provided for illustration purposes only because various changes and modifications within the spirit and scope of the invention will become apparent to those of skill in the art from the detailed description of the invention and claims that follow.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention:

FIG. 1 is an isometric view of an interposer;

FIG. 2 is an automatic test equipment test head according to one embodiment of the present invention;

FIG. 3 is an automatic test equipment test head according to a second embodiment of the present invention;

FIG. 4 is a side view of a test head and a wafer-interposer assembly during testing according to one embodiment of the present invention;

FIG. 5 is a cutaway view of the wafer-interposer assembly fixed to the positioning device; and

FIG. 6 is a flowchart showing one embodiment of the methods of the present invention.

### DETAILED DESCRIPTION OF THE INVENTION

Although making and using various embodiments of the present invention are discussed herein in terms of testing a wafer-interposer assembly, it should be appreciated that the present invention provides many applicable inventive concepts that can be embodied in a wide variety of specific contexts. The specific embodiments discussed herein are merely illustrative of specific ways to make and use the invention and do not limit the scope of the invention.

The embodiments of the invention disclosed herein comprise methods for electrically testing a wafer-interposer assembly in an efficient and cost effective manner. In one embodiment, the method of the present invention incorporates an automated positioning mechanism to bring the wafer interposer in contact with the test head of automatic test equipment (ATE). In certain embodiments, the load board and software of the ATE is configured to test multiple devices in parallel. After one device or group of devices is tested, the interposer is repositioned to test the next device or group of devices. In certain embodiments, software evaluates and stores the results of each device test and sorts the devices into good and bad groups, or according to a range of performance levels, after the wafer-interposer assembly is diced into individual circuits.

The present invention provides a method for electrically testing a wafer interposer that overcomes the limitations of testing bare singulated die. More specifically, the present invention provides a method for testing die in wafer form prior to dicing the wafer into individual circuits.

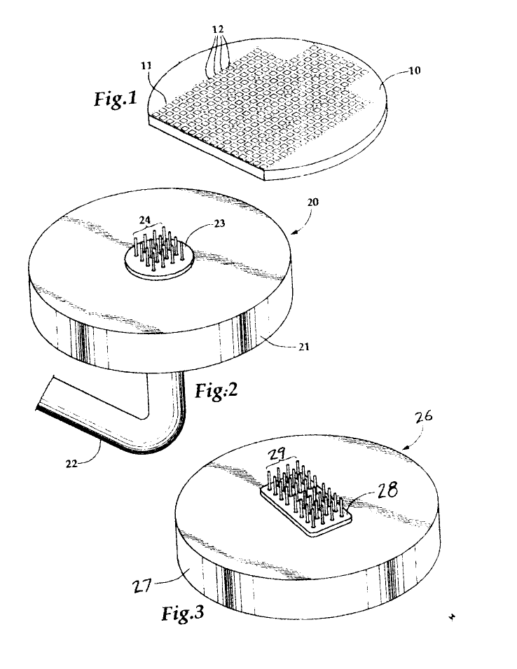

FIG. 1 shows the topside of a wafer interposer 10. In one embodiment, interposer 10 comprises a generally flat dielectric sheet having an array of conductive contacts 12 on each side. A semiconductor wafer (not shown) is attached to the bottom of interposer 10. In certain embodiments, a single wafer contains many individual integrated circuit devices, or dies. In most cases, each of the dies in a wafer has multiple contact pads. In most embodiments, the contact pads on the wafer side of interposer 10 are disposed in a pattern matching the pattern of contact pads on the wafer, with each contact pad on the wafer having a corresponding contact pad on the wafer side of the interposer 10. Connectors within the interposer 10 connect the array of contact pads facing the wafer to the contacts 12 on the top surface of the interposer 10. In certain embodiments, contacts 12 are larger than the contact pads on the wafer. In certain embodiments, contacts 12 are arranged in an array having a greater pitch than the contact pads on the wafer.

The use of interposer 10 allows testing at the wafer level before dicing, eliminates the need for temporarily packaging the die in a carrier, and allows for simultaneous or near simultaneous testing multiple wafer-interposer assemblies. As a result, the number of manufacturing operations are reduced, thereby improving first pass yields. In addition, manufacturing time is decreased, thereby improving cycle times and avoiding additional costs.

Moreover, the interposer 10 enables testing and burn-in of all die at the wafer level. For example, the interposer 10 eliminates the need to singulate, package, test, then unpackage each die individually to arrive at a Known Good Die product stage. This results in a significant cost avoidance opportunity for wafer manufacturers. Furthermore, the interposer 10 may remain attached to the die following dicing, thereby providing the additional benefit of redistributing the die I/O pads to a standard Joint Electrical Dimensional Electronic Committee (“JDEC”) interconnect pattern for Direct Chip Attachment (“DCA”) applications.

Interposer 10 includes one or more layers having etched routing lines and vias therein, which serve as electrical conductors. At least one set of conductors passes through the interposer 10 to electrically connect the pads on the wafer to the pads of a substrate to which the chip assembly will be attached. The conductors are selected to have suitable conductivity and may be, for example, copper.

FIG. 1 shows an array of interposer contact arrays, including array 11, on the surface of interposer 10, each of which corresponds to the array of contacts for an individual die in the wafer. Accordingly, each contact pad 12 on interposer 10 corresponds to a contact pad on the wafer. In this example, each die has 16 contact pads. Although this embodiment shows die contact array 11 having 16 contact pads, each semiconductor die may have more or fewer pads. In certain embodiments, all of the contact pads 12 of array 11 must be in electrical contact with the connectors of the test head of an ATE simultaneously in order to fully test the die that corresponds to array 11 on interposer 10. In other embodiments, testing may be performed using fewer than all of the contact pads 12.

The interposer 10 is preferably directly and permanently attached to the wafer, thereby eliminating the wafer-bumping step traditionally required for Flip chip and Flip chip/DCA applications. Assembly of the interposer 10 and wafer is accomplished through creation of a set of permanent electrical and mechanical connections between the interposer 10 and wafer using some form of conductive attachment elements. The conductive attachment elements will typically be implemented as features on both the upper and lower surfaces of the interposer 10, but may alternatively be placed on the wafer. Likewise, the attachment elements could be incorporated into a sheet or similar structure sandwiched between the interposer 10 and wafer during assembly. The method of attachment of the contact pads on the wafer to the contact pads on the interposer 10 can be accomplished by a number of other devices known to those of skill in the art, including but not limited to solder balls, two-part or heat-cured conductive epoxy, and conductive thermoplastic balls or bumps.

Alternately, the interposer 10 may be created by application of materials on the wafer itself, such as ink jet deposition of conductive epoxy, solder or polyimide. These materials can also be rolled on, sprayed on or applied through stereolithographic technologies. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the interposer 10.

FIG. 2 shows one embodiment of an ATE test head 20 useful with the methods of the present invention. In the embodiment shown in FIG. 2, test head body 21 of test head 20 contains certain portions of the electronic circuitry required for testing of a semiconductor device. Additional circuitry and test control hardware may reside in other components of the ATE (not shown). Communication between the test head 20 and any off-board electronics is typically through a cable such as cable 22.

In the embodiment shown in FIG. 2, a load board 23 is attached to the test head body 21. The load board 23 is customized to test an individual semiconductor device. One advantage of this embodiment of the invention relates to high frequency signals required for testing of certain high-speed devices. For these devices, it is desirable that the signal path between the test head 20 and the contact pads 12 be short. Furthermore, it has been shown that movement of the signal cables connecting the test head 20 to other portions of the ATE can cause variation in the signal characteristics. Accordingly, certain embodiments of the present invention incorporate a stationary fixed test head 20.

In the embodiment shown in FIG. 2, electrical contact with the pads 12 of the interposer 10 is accomplished by means of an array of contacts 24 on the load board 23. In certain embodiments, the pads 12 on the interposer 10 are relatively large and have relatively wide pitches, so that contacts 24 on the load board 23 do not have to be disposed on as fine a pitch as they might otherwise need to be if they were in direct contact with the wafer. Contacts 24 can comprise mechanical springs, pogo pins, short needles, conductive epoxy or any other contact system known to those of skill in the art.

In certain embodiments, the load board 23 may incorporate additional contacts 24 for the purpose of testing additional devices in parallel. FIG. 3 shows an embodiment of a test head 26 comprising a test head body 27 having a load board 28 with an arrangement of contacts 29 suitable for connecting to contact pads 12 on multiple devices simultaneously. In the embodiment shown in FIG. 3, load board 28 is attached to the test head body 27 and is customized to test multiple semiconductor devices in parallel. Load board 28 incorporates thirty-two contacts 29 arranged in two 4 by 4 arrays, but additional contacts 29 may be used in other embodiments. If test head 26 contains 64 test channels, for example, then four 16-pin devices can be tested in parallel simultaneously. In such an embodiment, the load board 28 would require sixty-four contacts 29. The contacts 29 would be arranged in a geometry mirroring a pattern of sixty-four contacts 29 on the surface of interposer 10.

As with the embodiment shown in FIG. 2, one advantage of this embodiment of the invention relates to high frequency signals required for testing of certain high-speed devices. For these devices, it is desirable that the signal path between the test head 26 and the contact pads 12 be short. Furthermore, it has been shown that movement of the signal cables connecting the test head 26 to other portions of the ATE can cause variation in the signal characteristics. Accordingly, certain embodiments of the present invention incorporate a stationary fixed test head 26.

In the embodiment shown in FIG. 3, electrical contact with the pads 12 of the interposer 10 is accomplished by means of an array of contacts 29 on the load board 28. In certain embodiments, the pads 12 on the interposer 10 are relatively large and have relatively wide pitches, so that contacts 29 on the load board 28 do not have to be disposed on as fine a pitch as they might otherwise need to be if they were in direct contact with the wafer. Contacts 29 can comprise mechanical springs, pogo pins, short needles, conductive epoxy or any other contact system known to those of skill in the art.

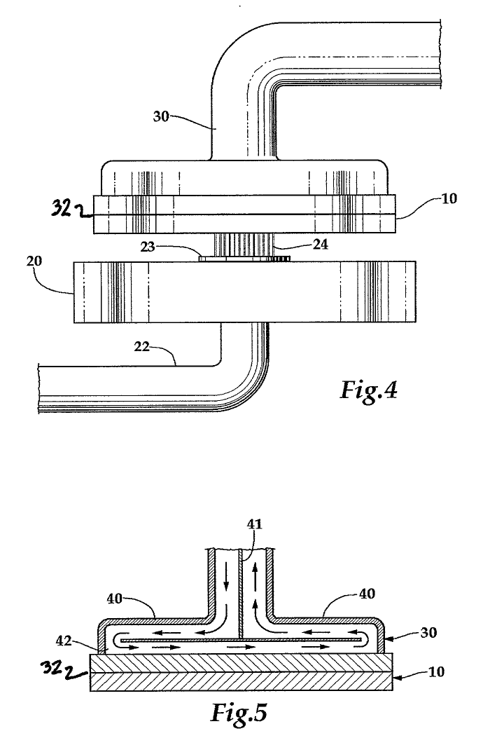

FIG. 4 shows the arrangement of test head 20 and a wafer-interposer assembly 32 during testing. Although the description that follows relates to test head 20 of FIG. 2, it will be appreciated by one of skill in the art that the same discussion would apply in the same manner to test head 26 of FIG. 3. In certain embodiments, test head 20 can be a foot or more in diameter and can weigh up to 100 pounds or more. For these embodiments, it may be desirable for test head 20 to remain stationary during the testing process, while wafer-interposer assembly 32 is moved and positioned to test devices by a positioning device 30. In certain embodiments, positioning device 30 picks up and holds wafer-interposer assembly 32 using a holding mechanism, and then moves it into place adjacent to the test head 20 with the contacts 24 facing the test head 20. A number of devices are suitable for performing the functions of device 30, as will be appreciated by one of skill in the art. Once in position adjacent to test head 20, wafer-interposer assembly 32 is moved closer to test head 20 until contact is made to the contact pins 24 on the load board 23. It will be appreciated that the orientation of test head 20 and positioning device 30 is merely illustrative, and that other orientations may be employed in other embodiments.

After electrical connection to the test head 20, the device or devices connected to contact pads 12 of the wafer-interposer assembly 32 can be run through one or more performance tests. In certain embodiments, such testing may comprise a full parametric burn in test. During the course of a full parametric burn in test, each of the separate functions may be tested across a range of conditions, so as to simulate real world operation. Alternately, a more limited test can be performed on one or only a few characteristics of the device or devices. In certain embodiments, the test head 20 may incorporate a device for vibrating or otherwise mechanically stressing the devices during testing.

After testing is complete for the first device or set of devices, the wafer-interposer assembly 32 is repositioned by the positioning device 30 to test the next device or set of devices. In certain embodiments, the test results for each device are recorded by the ATE for use in sorting the devices after the wafer-interposer assembly 32 is diced into individual devices. Once testing of all devices on the wafer-interposer assembly 32 is complete, the wafer-interposer assembly 32 is moved away from test head 20 and another wafer-interposer assembly 32 is picked up for testing.

In certain embodiments, the software map of the test results of each device are correlated with the particular wafer-interposer assembly 32 tested. This can be accomplished by tracking its position in the work holder or by coding an identification number directly onto the wafer-interposer assembly 32. In certain embodiments, the identification may comprise a barcode identification number. In certain embodiments, an identification number reader is located on the load board 23.

FIG. 5 shows a cutaway view of a wafer-interposer 32 secured by a positioning device 30. In this embodiment, vacuum is used to secure the wafer-interposer assembly 32 through channels 40. In other embodiments, mechanical end effectors or other devices may be employed, as will be appreciated by one of skill in the art.

Testing of devices at a particular temperature or across a range of temperatures is often required. In certain embodiments, positioning device 30 contains a baffle 41 in the center, forming a path for air or other fluid to move down the positioning device 30 and over the wafer. This fluid is then returned for recirculation. The flow of fluid is depicted by arrows in FIG. 5. In other embodiments, recirculation may be effectuated through coaxial tubes or other geometries.

If high temperature testing is required, then a heated fluid, such as air, is circulated over the interposer assembly 10. In certain embodiments, a thermocouple 42 is mounted on the positioning device 30 such that it is in contact with the interposer assembly 10 during testing. In certain embodiments, thermocouple 42 is used to control the fluid temperature for the devices under test. Cold temperature testing can be accomplished in the same way. Extreme cold temperature testing can be performed using evaporated liquid nitrogen circulated over the interposer assembly 10.

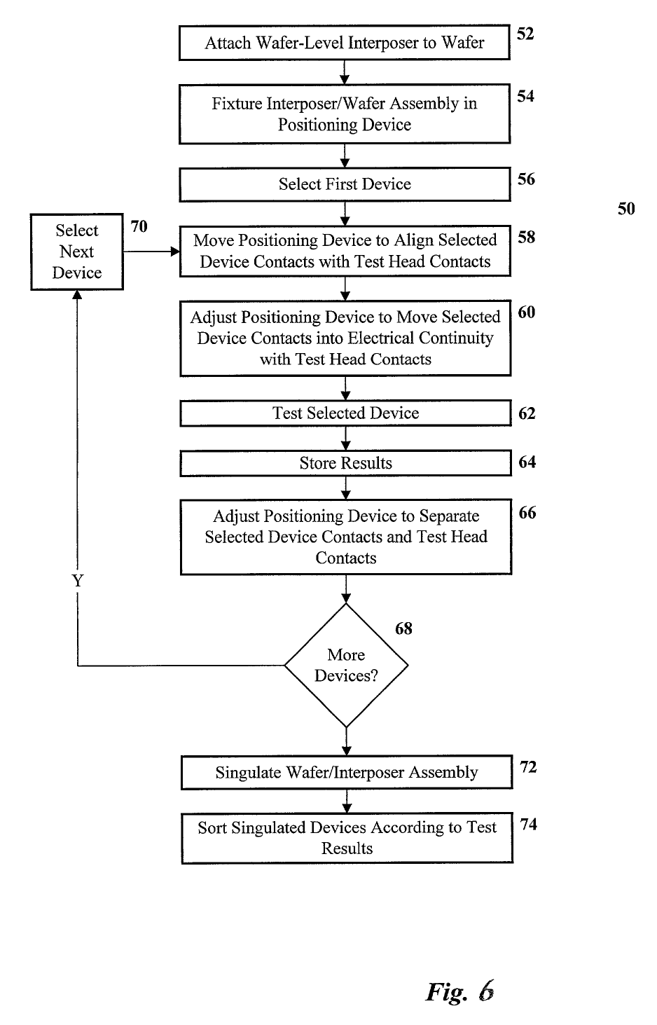

FIG. 6 depicts a flowchart 50 showing one embodiment of the method of the present invention. The process of wafer testing begins in block 52, wherein the interposer is attached to the wafer. The wafer-interposer assembly 32 is then fixed 54 into the positioning device 30 and a device is selected for testing 56. The positioning device 30 is moved so as to align the contacts 12 of the selected device with the contacts 24 of the test head 20, as described in block 58.

After the contact pads 12 of the selected device and the contacts 24 of the test head are aligned, the distance between the wafer-interposer assembly 32 and the test head 20 is adjusted until the contacts 24 are in sufficient electrical continuity with the contact pads 12 for reliable testing, as described in block 60. The device is tested 62 and the results of the testing are stored 64.

After testing is complete, the position of the wafer-interposer assembly 32 is adjusted to separate the test head contacts 24 from the contact pads 12, as described in block 66. If more devices remain to be tested 68, a new device is selected 70 and process flow returns to block 58, where the positioning device 30 is moved to align the contact pads 12 of the selected device with the contacts 24 of the test head 20. If there are no further devices to be tested, the wafer-interposer assembly 10 is singulated into individual devices 72 and sorted according to test results 74.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive or to limit the scope of the invention. Many modifications and variations are possible in light of the above teaching without departing from the spirit and scope of the following claims. It is contemplated that the use of the present invention can involve components having different characteristics. It is intended that the scope of the present invention be defined by the claims appended hereto, giving full cognizance to equivalents in all respects.

What is claimed is:

1. A method for testing an integrated circuit disposed in a semiconductor wafer, the method comprising the steps of:
attaching the semiconductor wafer to a first surface of an interposer such that one or more contact pads on a second surface of the interposer are electrically connected to one or more contact pads of the integrated circuit by one or more electrical conductors passing through the interposer;
fixing the semiconductor wafer to a positioning device using a holding mechanism in such a manner that all or part of the second surface of the interposer is accessible;
adjusting the position of the positioning device to bring one or more contact pads of the interposer into electrical contact with one or more electrical contacts of a test head; and
testing the integrated circuit through the electrical contacts of the test head.

2. The method as recited in claim 1, further comprising the step of cycling the semiconductor wafer through a range of temperatures.

3. The method as recited in claim 2 wherein the step of cycling the semiconductor wafer through a range of temperatures is performed by applying a temperature-controlled fluid to the semiconductor wafer via the holding mechanism.

4. The method as recited in claim 3 wherein the temperature-controlled fluid is air.

5. The method as recited in claim 3 wherein the temperature-controlled fluid is liquid nitrogen.

6. The method as recited in claim 2, further comprising the step of monitoring the temperature of the semiconductor wafer using a thermocouple.

7. The method as recited in claim 1 wherein the test head is stationary.

8. The method as recited in claim 1, further comprising the step of reading an identification code imprinted on the interposer.

9. The method as recited in claim 1, further comprising the step of singulating the semiconductor wafer-interposer into one or more chip assemblies.

10. A method for testing an integrated circuit device disposed in a semiconductor wafer comprising the steps of:
providing an interposer having a first array of contacts on a first side and a second array of contacts, each electrically connected to one of the contacts in the first array, on a second side;
attaching a semiconductor wafer to the first side of the interposer so that the first array of contacts are electrically connected to the integrated circuit;
fixing the wafer in a holding mechanism attached to a positioning device;
adjusting the position of the positioning device to align one or more of the contacts in the second array with one or more electrical contacts of a test head;
adjusting the position of the positioning device to bring one or more of the contacts in the second array into contact with one or more electrical contacts of the test head; and
testing the integrated circuit device through the electrical contacts of the test head.

11. The method as recited in claim 10, further comprising the step of cycling the semiconductor wafer through a range of temperatures.

12. The method as recited in claim 11 wherein the step of cycling the semiconductor wafer through a range of temperatures is performed by applying a temperature-controlled fluid to the semiconductor wafer via the holding mechanism.

13. The method as recited in claim 12 wherein the temperature-controlled fluid is air.

14. The method as recited in claim 12 wherein the temperature-controlled fluid is liquid nitrogen.

15. The method as recited in claim 11, further comprising the step of monitoring the temperature of the semiconductor wafer using a thermocouple.

16. The method as recited in claim 10 wherein the test head is stationary.

17. The method as recited in claim 10, further comprising the step of reading an identification code imprinted on the interposer.

18. The method as recited in claim 10, further comprising the step of mechanically stressing the semiconductor wafer during testing.

19. The method as recited in claim 10 wherein the holding mechanism comprises a vacuum applied to the semiconductor wafer.

20. The method as recited in claim 10, further comprising the step of singulating the semiconductor wafer-interposer into one or more chip assemblies.

21. A method for testing two or more integrated circuit devices disposed in a semiconductor wafer comprising:
providing an interposer having a first array of contacts on a first side and a second array of contacts, each electrically connected to one of the contacts in the first array, on a second side;
attaching the semiconductor wafer to the first side of the interposer;
fixing the semiconductor wafer and interposer assembly in a holding mechanism attached to a positioning device;
adjusting the position of the positioning device to bring one or more of the contacts in the second array into contact with one or more electrical contacts of the test head;
testing the one or more integrated circuit devices through the electrical contacts of the test head;
singulating the wafer and interposer assembly into individual integrated circuit devices; and
sorting the individual integrated circuit devices according to the results of the tests performed on each integrated circuit device.

22. The method as recited in claim 21, further comprising the step of cycling the semiconductor wafer through a range of temperatures.

23. The method as recited in claim 22 wherein the step of cycling the semiconductor wafer through a range of temperatures is performed by applying a temperature-controlled fluid to the semiconductor wafer via the holding mechanism.

24. The method as recited in claim 23 wherein the temperature-controlled fluid is air.

25. The method as recited in claim 23 wherein the temperature-controlled fluid is liquid nitrogen.

26. The method as recited in claim 22, further comprising the step of monitoring the temperature of the semiconductor wafer using a thermocouple.

27. The method as recited in claim 21 wherein test head is stationary.

28. The method as recited in claim 21, further comprising the step of reading an identification code imprinted on the interposer.

29. The method as recited in claim 21, further comprising the step of mechanically stressing the semiconductor wafer during testing.

30. The method as recited in claim 21 wherein the holding mechanism comprises a vacuum applied to the semiconductor wafer.

31. The method as recited in claim 20 wherein the step of testing the one or more integrated circuit devices comprises a full burn-in test.
